(19) United States
(12) Patent Application Publication
(10) Pub. No.: US 2026/0082554 A1
(43) Pub. Date: Mar. 19, 2026

(54) SEMICONDUCTOR STRUCTURES AND METHODS FOR FORMING THE SAME

(71) Applicant: Winbond Electronics Corp., Taichung City (TW)

(72) Inventors: Chi-Ching LIU, Taichung City (TW); Chung-Hsien LIU, Taichung City (TW)

(21) Appl. No.: 19/234,607

(22) Filed: Jun. 11, 2025

(30) Foreign Application Priority Data
Sep. 19, 2024 (TW) 113135466

(51) Int. Cl. H10B 41/30; H10D 30/01; H10D 30/68

(52) U.S. Cl. CPC H10B 41/30; H10D 30/0411; H10D 30/683; H10D 30/6891

(57) ABSTRACT

A semiconductor structure is provided. The semiconductor structure includes a substrate, a tunneling dielectric layer disposed on the substrate, a plurality of transistor structures disposed on the tunneling dielectric layer. Each transistor structure includes a floating gate, an inter-gate dielectric layer, and a control gate sequentially disposed on the tunneling layer. In a cross-sectional view along a first direction, the control gate is disposed between opposing sidewalls of the floating gate.

### CROSS REFERENCE TO RELATED APPLICATIONS

This Application claims priority of Taiwan Patent Application No. 113135466, filed on Sep. 19, 2024, the entirety of which is incorporated by reference herein.

### BACKGROUND OF THE INVENTION

### Field of the Invention

The present invention relates to a semiconductor device, and, in particular, it relates to a semiconductor device with the setting of floating gate and control gate.

### Description of the Related Art

As the size of electronic products and semiconductor devices continues to shrink, many challenges arise. For example, the floating gate can easily become damaged by the process of manufacturing the semiconductor. In addition, it is difficult to deposit a control gate using polysilicon due to the tight spacing (for example, the formation of air gaps and the like). Therefore, the industry still needs to improve the manufacturing method of flash memory to overcome the problems caused by scaling down.

### BRIEF SUMMARY OF THE INVENTION

The present invention provides a semiconductor structure, which includes a substrate, a tunneling dielectric layer disposed on the substrate, and a plurality of transistor structures disposed on the tunneling dielectric layer. Each transistor structure includes a floating gate, an inter-gate dielectric layer, and a control gate, which are sequentially disposed on the tunneling dielectric layer. In the cross-sectional view along the first direction, the control gate is disposed between opposing sidewalls of the floating gate.

The present invention provides a method for forming a semiconductor structure. The method includes providing a substrate. The method includes forming a tunneling dielectric layer on the substrate. The method includes forming a plurality of first sacrificial layers on the tunneling dielectric layer and extending along a first direction. The method includes forming a plurality of floating gates and a plurality of inter-gate dielectric layers on opposing sidewalls of a plurality of first sacrificial layers. The method includes replacing the first sacrificial layers with a plurality of sidewall protective layers. The method includes forming a plurality of control gates on the sidewalls of the inter-gate dielectric layers.

### BRIEF DESCRIPTION OF THE DRAWINGS

The present invention can be more fully understood by reading the subsequent detailed description and examples with references made to the accompanying drawings, wherein:

FIG. 1 is a top view of a semiconductor structure according to some embodiments of the present invention.

FIG. 2A and FIG. 2B are cross-sectional views corresponding to cross-sectional line AA′ and cross-sectional line BB′ according to some embodiments of the present invention.

FIGS. 3A-18A are cross-sectional views corresponding to the semiconductor structure of FIG. 2A according to some embodiments of the present invention.

FIGS. 3B-18B are cross-sectional views corresponding to the semiconductor structure of FIG. 2B according to some embodiments of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

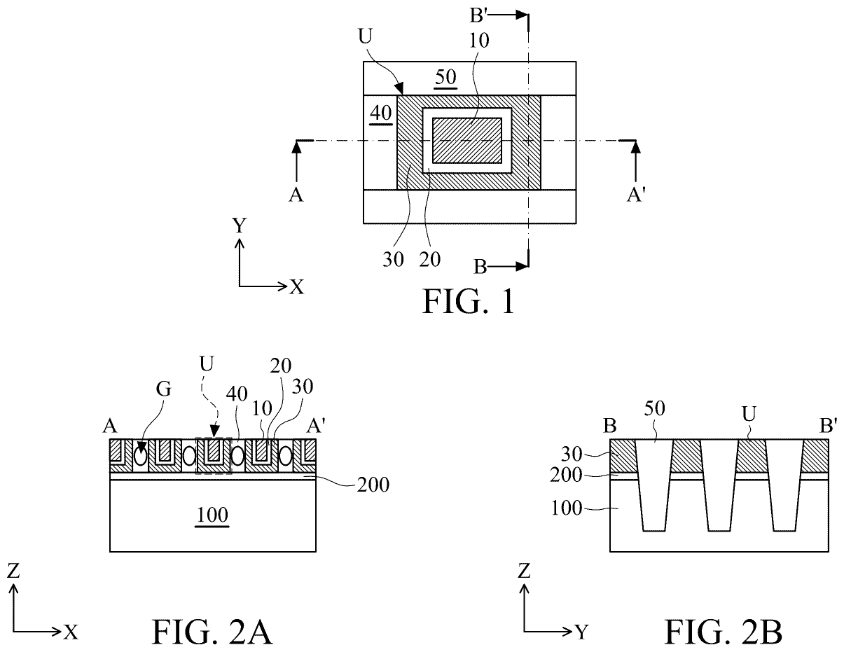

FIG. 1 is a top view of a semiconductor structure according to some embodiments of the present invention. The transistor structure U included in the semiconductor structure includes a control gate 10, an inter-gate dielectric layer 20 surrounding the control gate 10, and a floating gate 30 surrounding the inter-gate dielectric layer 20. As the control gate 10 viewed as the center, the inter-gate dielectric layer 20 and the floating gate 30 are sequentially disposed outward. The floating gate 30 surrounds the control gate 10. The transistor structure U shown in FIG. 1 is rectangular, but those skilled in the art should be able to understand that the transistor structure U may be circular, elliptical, or irregular in actual products as long as the floating gate 30 may surround the inter-gate dielectric layer 20 and the control gate 10.

The semiconductor structure further includes a sidewall protective layer 40 on two sides of the floating gate 30 and an isolation component 50 on the other two sides of the floating gate 30. In FIG. 1, the isolation component 50 and the sidewall protective layer 40 extend along a first direction X and a second direction Y perpendicular to the first direction X, respectively. The isolation component 50 and the sidewall protective layer 40 surround the transistor structure U, and there is no particular limitation on its extending direction.

Referring to FIG. 2A and FIG. 2B, they are cross-sectional views taken along the section line AA′ and the section line BB′ of FIG. 1, respectively. FIG. 2A and FIG. 2B illustrate cross-sectional views of a plurality of transistor structures U. The relative positions of the various components are described in detail below.

As shown in FIG. 2A, the semiconductor structure includes a substrate 100, a tunneling dielectric layer 200 disposed on the substrate 100, and a plurality of transistor structures U disposed on the tunneling dielectric layer 200. Each transistor structure U includes a floating gate 30, an inter-gate dielectric layer 20, and a control gate 10 sequentially disposed on the tunneling dielectric layer. In the cross-sectional view along the first direction X (FIG. 2A), the control gate 10 is disposed between the opposing sidewalls of the floating gate 30.

As shown in FIG. 2A, the top surface of the floating gate 30 is coplanar with the top surface of the control gate 10. As shown in FIG. 2A, the floating gate 30 is separated from the sidewalls and the bottom of the control gate 10 by the inter-gate dielectric layer 20. As shown in FIG. 2A, the floating gate 30 and the inter-gate dielectric layer 20 are U-shaped.

As shown in FIG. 2A, a sidewall protective layer 40 is further included between the two transistor structures U to isolate the two transistor structures U. That is, the transistor structures U and the sidewall protective layers 40 are arranged in an alternating manner. As shown in FIG. 2A, the sidewall protective layer 40 has an air gap G therein to further prevent mutual interference between two transistors.

In the cross-sectional view along the first direction Y (FIG. 2B), an isolation component 50 is further included between the two transistor structures U. As shown in FIG. 2B, the isolation component 50 penetrates through the floating gate 10 and the tunneling dielectric layer 200 into the substrate 100. The isolation components 50 may be considered as an insulating region, and the region between the isolation components 50 may be considered as an active region. Since the sectional line BB′ does not pass through the control gate 10, the transistor structure U in FIG. 2B only shows the floating gate 30 but does not show the control gate 10.

As described above, by disposing the control gate 10 between the two sidewalls of the floating gate 30, the spacing between the transistor structures U may be further reduced, thereby miniaturizing the semiconductor structure.

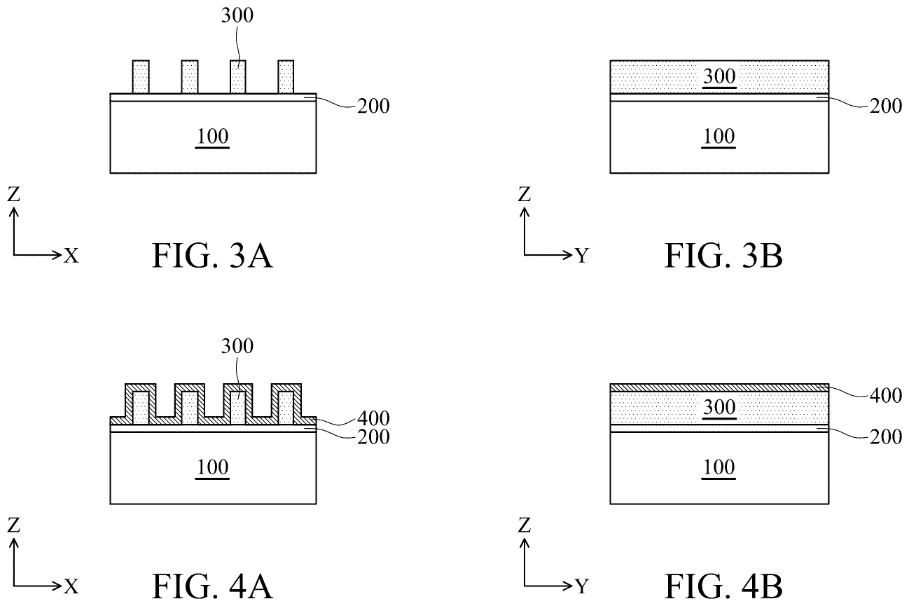

FIGS. 3A-18A are cross-sectional views corresponding to the semiconductor structure formed in FIG. 2A. FIGS. 3B-18B are cross-sectional views corresponding to the semiconductor structure formed in FIG. 2B.

Referring to FIGS. 3A and 3B, a substrate 100 is provided. The substrate 100 may be an elemental semiconductor substrate, such as a silicon substrate or a germanium substrate; or a compound semiconductor substrate, such as a silicon carbide substrate, a gallium arsenide substrate, a gallium phosphide substrate, an indium phosphide substrate, an indium arsenide substrate and/or an indium antimonide; or alloy semiconductor, such as SiGe, GaAsP, AlInAs, AlGaAs, GaInAs, GaInP, GaInAsP, and/or combinations thereof. The substrate 100 may be a semiconductor base on an insulator. The substrate 100 has a first doping concentration of a first conductivity type (such as P type).

Continuing to refer to FIG. 3A and FIG. 3B, a tunneling dielectric layer 200 is formed on the substrate 100. The tunneling dielectric layer 200 may include oxide, nitride, oxynitride, or a combination thereof. The tunneling dielectric layer 200 may be silicon oxide, silicon nitride, silicon oxynitride, a high-k material, or a combination thereof. The high dielectric constant material may be metal oxide, metal nitride, metal silicide, transition metal oxide, transition metal nitride, transition metal silicide, metal oxynitride, metal aluminate, zirconium silicate, zirconate aluminate.

The tunneling dielectric layer 200 may be formed by a deposition process or a thermal oxidation process. The aforementioned deposition process may include a chemical vapor deposition (CVD) process, a physical vapor deposition (PVD) process, an atomic layer deposition (ALD) process or other suitable processes.

Continuing to refer to FIG. 3A and FIG. 3B, a plurality of first sacrificial layers 300 is formed on the tunneling dielectric layer 200 and extends along the second direction Y. In FIG. 3A, the first sacrificial layers 300 are spaced apart from each other. The first sacrificial layers 300 may include nitride, such as silicon nitride or silicon oxynitride. The formation of the first sacrificial layers 300 includes a deposition process, a patterning process, and the like. The aforementioned deposition process is similar to that described above. The aforementioned patterning process includes a lithography process and an etching process.

Referring to FIG. 4A and FIG. 4B, a floating gate material layer 400 is formed on the first sacrificial layers 300. As shown in FIG. 4A, the floating gate material layer 400 is formed on opposing sidewalls of the first sacrificial layers 300 and on the tunneling dielectric layer 200. The floating gate material layer is subsequently used as a floating gate, and includes a conductive material, such as doped or undoped polysilicon, amorphous silicon, metal, metal nitride, conductive metal oxide, or a combination thereof. The formation of the floating gate material layer 400 may include a deposition process, such as CVD, PVD, ALD, sputtering, resistance heating evaporation, electron beam evaporation or other suitable processes.

The formation of the floating gate material layer 400 may include multiple deposition processes and multiple etching processes to prevent the formation of gaps between the first sacrificial layers 300, thereby achieving a desired thickness value.

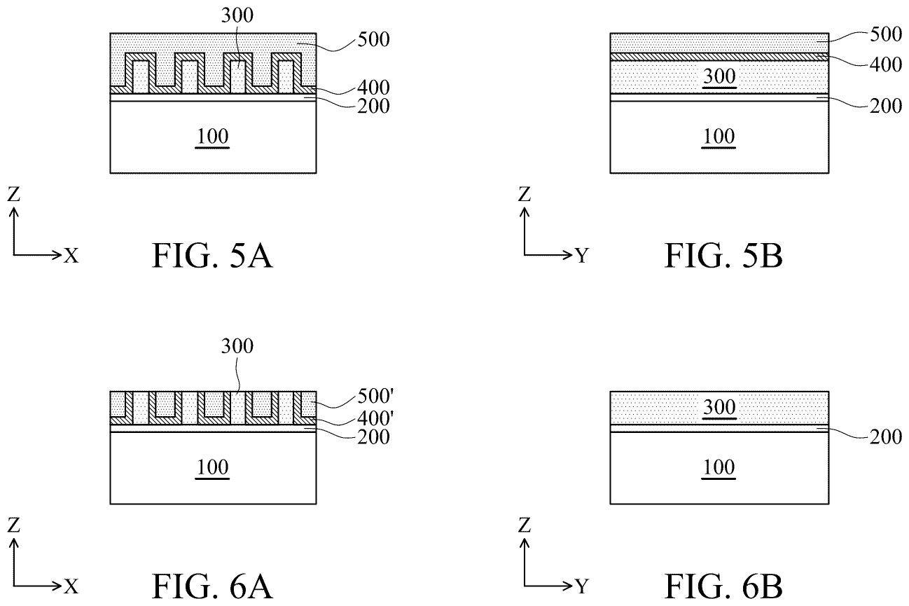

Referring to FIG. 5A and FIG. 5B, a second sacrificial layer 500 is formed on the floating gate material layer 400. As shown in FIG. 5A, the second sacrificial layer 500 is formed on the floating gate material layer 400 on the sidewall of the first sacrificial layer 300 and on the floating gate material layer 400 on the top surface of the first sacrificial layer 300. superior. The second sacrificial layer 500 may include a carbon-containing material (or carbide) or a carbon-based material, such as silicon carbide, spin on carbon (SOC), carbon or tetraethoxysilane (TEOS) oxide, diamond-like carbon (diamond-like carbon, DLC), amorphous carbon film (APF), high selectivity transparent (HST) film, or the like. The formation of the second sacrificial layer 500 may include a deposition process similar to the above, which will not be described in detail herein. It should be noted that the second sacrificial layer 500 and the first sacrificial layer 300 are made of different materials, such as carbide and nitride, respectively, so as to have different etching selectivity.

Referring to FIG. 6A and FIG. 6B, the excessive second sacrificial layer 500 and the floating gate material layer 400 are removed. As shown in FIG. 6A, the floating gate material layer 400 and the second sacrificial layer 500 on the top surface of the first sacrificial layer 300 are removed. That is, the top surface of the first sacrificial layer 300 is exposed. Here, the remaining floating gate material layer 400 and the second sacrificial layer 500 are labeled as a plurality of floating gate layers 400′ and a plurality of second sacrificial layers 500′. Each floating gate layer 400′ covers one second sacrificial layer 500′, and the top surface of the floating gate layer 400′ is coplanar with the top surface of the second sacrificial layer 500. Removing the excessive second sacrificial layer 500 and the floating gate material layer 400 may include a removal process, such as a planarization process or an etching process.

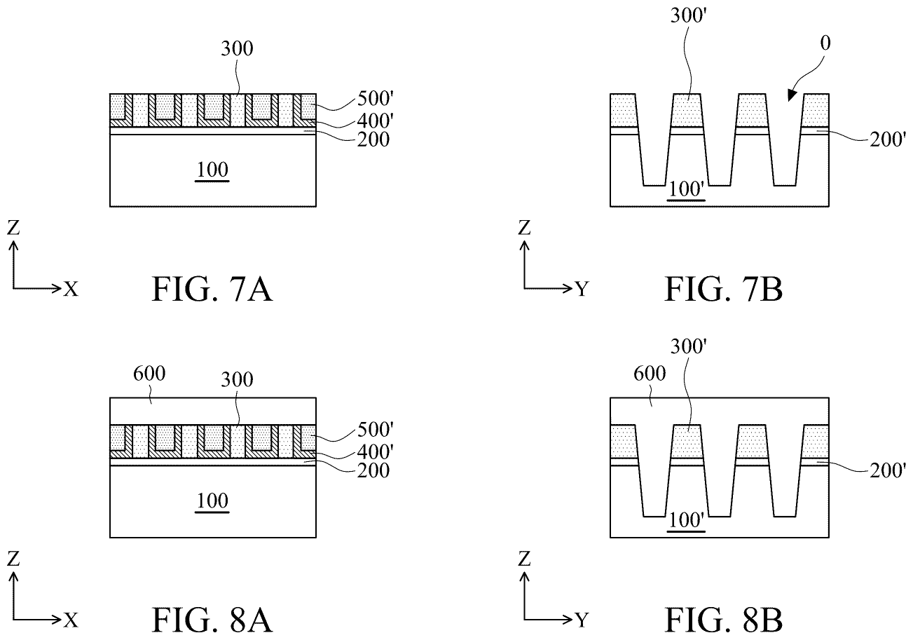

Please referring to FIGS. 7A and 7B, a plurality of trenches O are formed in the first direction X. As shown in FIG. 7B, the trenches O penetrate through the first sacrificial layer 300, the tunneling dielectric layer 200, and contacts the substrate 100. Here, the first sacrificial layer 300, the tunneling dielectric layer 200, and the substrate 100 are respectively labeled as the first sacrificial layer 300′, the tunneling dielectric layer 200′ and the substrate 100′ after the trenches O are formed. The formation of the trench O includes a lithography process and an etching process.

Referring to FIG. 8A and FIG. 8B, an isolation component material layer 600 is formed on the first sacrificial layer 300. As shown in FIG. 8B, an isolation component material layer 600 is formed in the trenches O. As shown in FIG. 8B, the isolation component material layer 600 is used as a subsequent isolation component, and includes a dielectric material, which may include silicon oxide, silicon nitride, silicon oxynitride, phosphosilicate glass, borophosphosilicate glass, fluorinated silicate glass, undoped silica glass, organosilicate glass, SiOₓC_{y}, spin-on glass (SOG), tetraethoxysilane, low-k dielectric material, or a combination thereof.

It should be noted that due to the scaling down of semiconductor structures, the aspect ratio of the trench O has also increased, air gaps (not shown) are easily generated when filling the isolation component material 600. In this way, the transistor structures may be further isolated from each other.

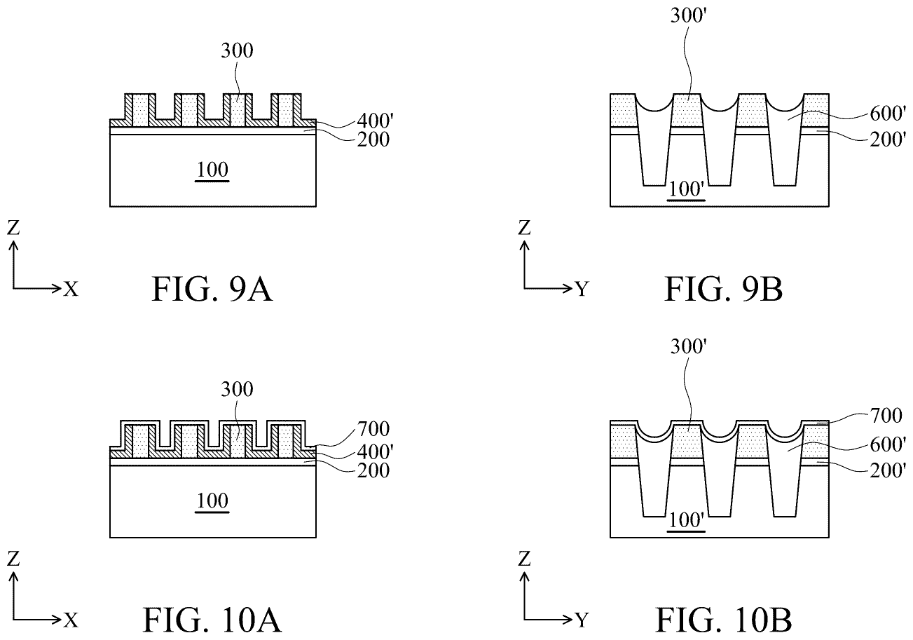

Referring to FIGS. 9A and 9B, the excessive isolation component material layer 600 is removed. That is, the isolation component material layer 600 on the top surface of the first sacrificial layer 300′(300) is removed. As shown in FIG. 9A, after the isolation component material layer 600 is removed, the second sacrificial layer 500′ surrounded by the floating gate layer 400′ is also removed. As shown in FIG. 9B, the remaining isolation component material layers 600 is labeled as a plurality of isolation material layers 600′. The isolation component material layer 600 is removed by the above-mentioned removal process. Furthermore, the second sacrificial layer 500′ may be removed by an etching process. It should be noted that since the second sacrificial layer 500 and the first sacrificial layer 300 respectively include carbide and nitride, the second sacrificial layer 500′ may be removed by an etching process having etching selectivity without substantially affecting the first sacrificial layer 300.

Next, referring to FIG. 10A and FIG. 10B, an inter-gate dielectric material layer 700 is formed on the first sacrificial layer 300. As shown in FIG. 10A, an inter-gate dielectric material layer 700 is formed on the bottom, sidewalls, and top surface of the floating gate layer 400′. As shown in FIG. 10B, the inter-gate dielectric material layer 700 is formed on the first sacrificial layer 300′ and the isolation material layer 600′. The inter-gate dielectric material layer 700 may include a high-k dielectric material, such as a multilayer structure of silicon oxide layer/silicon nitride layer/silicon oxide layer (oxide-nitride-oxide, ONO) or a single layer structure of hafnium oxide (HfO).

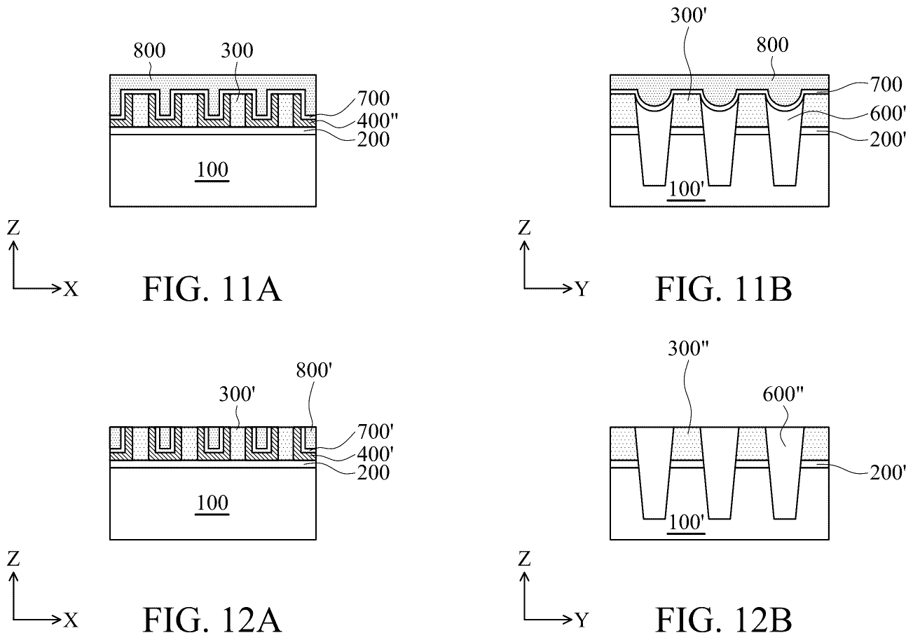

Next, please referring to FIG. 11A and FIG. 11B, a third sacrificial layer 800 on the inter-gate dielectric material layer 700 is formed. As shown in FIG. 11, the third sacrificial layer 800 is formed on the inter-gate dielectric material layer 700 on the sidewall of the floating gate layer 400′. The material and formation of the third sacrificial layer 800 are similar to those of the second sacrificial layer 500, and the third sacrificial layer 800 includes the same material as the second sacrificial layer 500.

Referring to FIG. 12A and FIG. 12B, the inter-gate dielectric layer 700 on the top surface of the first sacrificial layer 300 is cut off to expose the first sacrificial layer 300. Specifically, as shown in FIG. 12A, the inter-gate dielectric layer 700 and the third sacrificial layer 800 on the top surface of the first sacrificial layer 300 are removed. Furthermore, as shown in FIG. 12B, the inter-gate dielectric layer 700 and the third sacrificial layer 800 on the isolation component layer 600′ are removed. In this step, in order to ensure that the inter-gate dielectric layer 700 in FIG. 12A is cut off and the inter-gate dielectric layer 700 and the third sacrificial layer 800 in FIG. 12B are completely removed, the floating gate layer 400′ and the first sacrificial layer 300 will be slightly damaged. This step may reduce the height of the floating gate layer 400′ and the height of the first sacrificial layer 300. The floating gate layer 400′ in FIG. 12A is labeled as a floating gate 400″, the first sacrificial layer 300 is labeled as 300′, and the third sacrificial layer 800 is labeled as 800′. Similarly, this step may also reduce the height of the isolation material layer 600′ in FIG. 12B, so the isolation material layer 600′in FIG. 12B is labeled as an isolation component 600″, and the first sacrificial layer 300′ is labeled as a first sacrificial layer 300″. The removal of the third sacrificial layer 800 and the removal of a portion of the inter-gate dielectric material layer 700 are similar to the above-mentioned removal process.

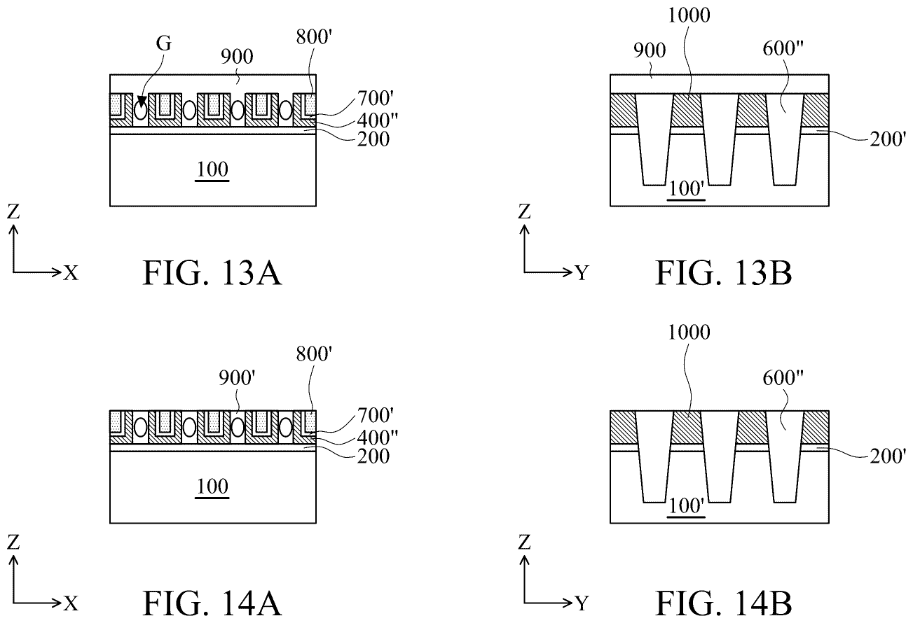

Referring to FIG. 13A and FIG. 13B, the first sacrificial layer 300′ (300) is removed and a sidewall protective material layer 900 and a floating gate 1000 are formed. Specifically, as shown in FIG. 13B, the first sacrificial layer 300′ may be removed while the mask covers the area of FIG. 13A. Also, a floating gate material layer is formed, and the excessive floating gate material layer is removed to expose the isolation component 600″ and form a floating gate 1000. Next, after removing the mask covering the area shown in FIG. 13A, the first sacrificial layer 300 is removed. Furthermore, as shown in FIGS. 13A and 13B, a sidewall protective material layer 900 is formed.

It should be noted that in a scaling-down semiconductor structure, the spacing between the transistor structures U becomes smaller. Therefore, when the sidewall protective material layer 900 is formed between the transistor structures U, an air gap G will be formed therein, as shown in FIG. 13A. The air gap G may further prevent the transistor structures U from interfering with each other.

The sidewall protective material layer 900 includes a dielectric material, such as silicon oxide, silicon nitride, silicon oxynitride, phosphosilicate glass (PSG), borophosphosilicate glass (BPSG), undoped Silicate Glass (USG), tetraethoxysilane (TEOS), low-k dielectric material, and/or other suitable dielectric materials. The formation of the sidewall protective material layer 900 includes a deposition process similar to that described above.

FIGS. 14A and 14B show the removal of the excessive sidewall protective material layer 900 to expose the floating gate 400″ (1000) and form a sidewall protective layer 900′. As shown in FIG. 14A, the sidewall protective layer 900′ still has an air gap G therein. Furthermore, the top surface of the sidewall protective layer 900′ is coplanar with the top surface of the floating gate 400. As shown in FIG. 14B, the top surface of the floating gate 1000 is coplanar with the top surface of the isolation component 600″.

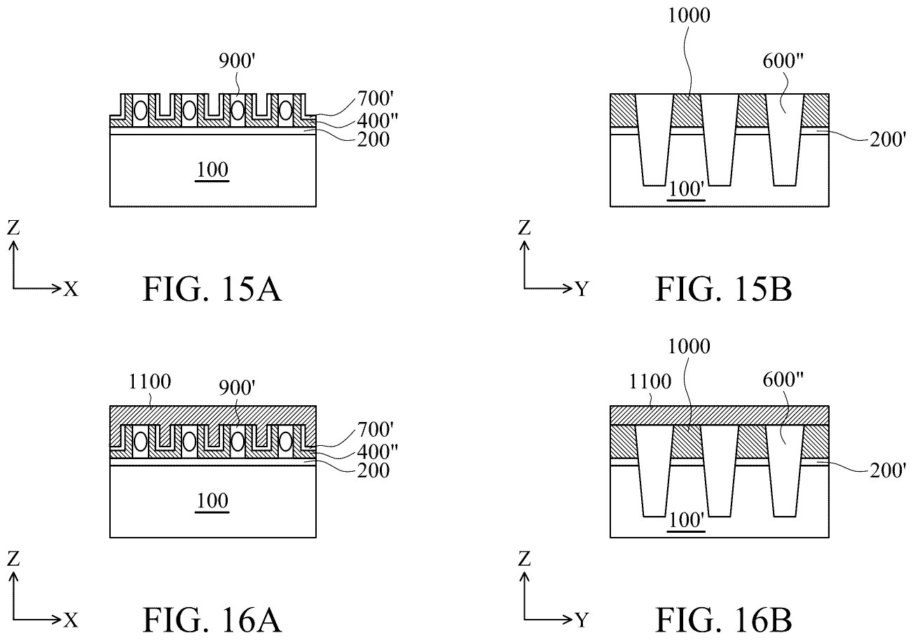

Referring to FIG. 15A and FIG. 15B, the third sacrificial layer 800′ is removed to expose the sidewalls of the inter-gate dielectric layer 700′. The removal of the third sacrificial layer 800′ is similar to the removal of the second sacrificial layer 500′. It should be noted that the third sacrificial layer 800′ and the sidewall protective layer 900′ may include different materials, such as carbide and oxide, so that the third sacrificial layer 800′ may be removed by an etching process having etching selectivity without substantially affecting the sidewall protective layer 900′.

Referring to FIG. 16A and FIG. 16B, a control gate material layer 1100 is formed on the floating gate 400″ (1000). The control gate material layer 1100 is subsequently used as a control gate, and includes a metal material, such as tungsten, aluminum, copper, gold, silver, other suitable metal materials, or a combination thereof. It should be noted that due to scaling down, polysilicon or metal silicide (such as cobalt silicide) which is difficult to reduce its own volume is not easy to form between the floating gates 400″. Therefore, in the embodiment, polysilicon or metal silicide is not used as the material of the control gate material layer. The formation of the control gate material layer 1100 includes a deposition process similar to the above.

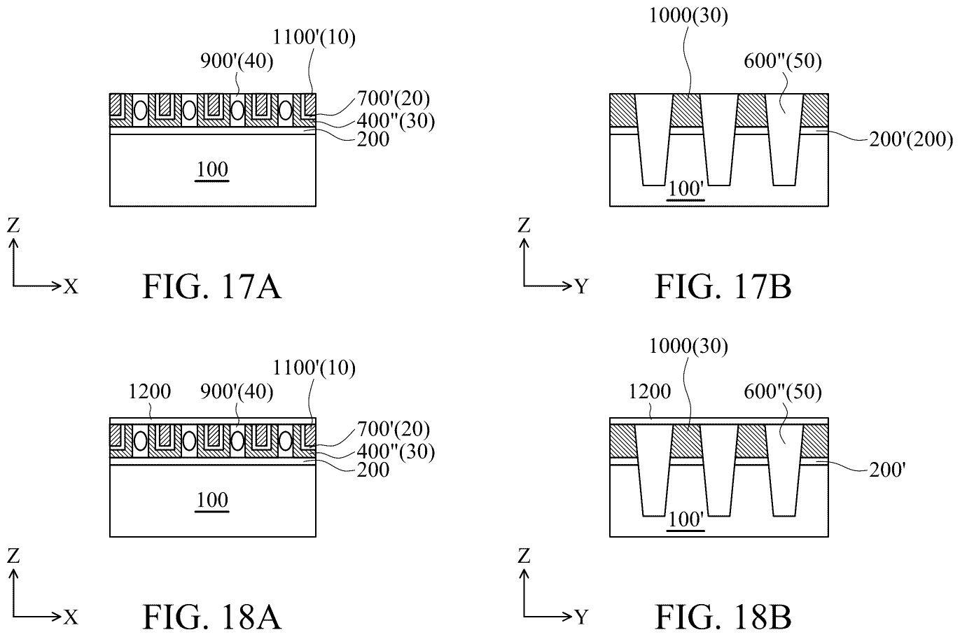

Referring to FIGS. 17A and 17B, the excessive control gate material layer 1100 is removed to expose the top surface of the floating gate 400″ (1000), and a control gate 1100′ is formed. It should be noted that FIG. 17A and FIG. 17B are equivalent to FIG. 2A and FIG. 2B. For ease of comparison, the same component symbols in FIG. 2A and FIG. 2B are labeled in brackets in FIG. 17A and FIG. 17B. In FIG. 17A and FIG. 17B, the floating gates are labeled 400″ and 1000 respectively, but they both correspond to the floating gates 30 in FIG. 2A and FIG. 2B. The removal of the control gate material layer 1100 includes a removal process similar to the above.

Referring to FIG. 18A and FIG. 18B, a top surface protective layer 1200 is formed on the floating gate 400″ (1000) and/or the control gate 1100′ to prevent subsequent processes from damaging the transistor structure. The top protective layer 1200 includes a dielectric material, such as an oxide or a nitride, for example silicon carbide nitride (SiCN). In the case of subsequent processes using copper, the top surface protective layer 1200 is preferably made of nitride to prevent copper from penetrating into the top surface protective layer 1200 and affecting the transistor structure.

The embodiments of the present invention reduce a process that exposes the floating gate, thereby reducing the risk of damage to the floating gate and lowering the cost. In addition, by using a metal material to form the control gate, the risk of air gaps being generated when using polysilicon or metal silicide due to scaling down may be reduced.

In summary, the embodiments of the present invention may further scaling down the semiconductor structure by making the floating gate present a U-shape and surround the control gate. Furthermore, the control gates in the array region are all formed of metal materials to overcome the problem that polysilicon or metal silicide cannot be completely filled. The control gate is embedded in the U-shaped floating gate in the form of a plug, thereby reducing a process of exposing the floating gate and simplifying the complexity and cost of the process.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate;
a tunneling dielectric layer disposed on the substrate;
a plurality of transistor structures disposed on the tunneling dielectric layer, wherein each transistor structure comprises:
a floating gate, an inter-gate dielectric layer, and a control gate sequentially disposed on the tunneling layer, wherein in a cross-sectional view along a first direction, the control gate is disposed between opposing sidewalls of the floating gate.

2. The semiconductor structure as claimed in claim 1, wherein a top surface of the floating gate is coplanar with a top surface of the control gate.

3. The semiconductor structure as claimed in claim 1, wherein in a cross-sectional view along the first direction, the floating gate is spaced apart from opposing sidewalls and a bottom of the control gate by the inter-gate dielectric layer.

4. The semiconductor structure as claimed in claim 1, wherein in a cross-sectional view along the first direction, the floating gate is U-shaped.

5. The semiconductor structure as claimed in claim 1, further comprising a plurality of sidewall protective layers, wherein in a cross-sectional view along the first direction, the plurality of sidewall protective layers is disposed between the plurality of transistor structures.

6. The semiconductor structure as claimed in claim 5, wherein each sidewall protective layer and each transistor structure is arranged in an alternating manner.

7. The semiconductor structure as claimed in claim 5, wherein one of sidewall protective layers has an air gap.

8. The semiconductor structure as claimed in claim 1, wherein in a top view, the floating gate surrounds the inter-gate dielectric layer, and the inter-gate dielectric layer surrounds the control gate.

9. The semiconductor structure as claimed in claim 1, wherein in a top view, as the control gate viewed as a center, the inter-gate dielectric layer and the floating gate are sequentially disposed outward.

10. The semiconductor structure as claimed in claim 1, further comprising: a plurality of isolation components and a plurality of sidewall protective layers respectively extending along the first direction and a second direction, wherein the second direction is different from the first direction, and in a top view, the plurality of isolation components and the plurality of sidewall protective layers together surround the plurality of transistor structures.

11. The semiconductor structure as claimed in claim 10, wherein in a cross-sectional view along the second direction, the floating gate is disposed between the plurality of isolation components but the control gate is not disposed between the plurality of isolation components.

12. A method for forming a semiconductor structure, comprising:
providing a substrate;
forming a tunneling dielectric layer on the substrate;
forming a plurality of first sacrificial layers on the tunneling dielectric layer, wherein the plurality of first sacrificial layers extends along a first direction;
forming a plurality of floating gates and a plurality of inter-gate dielectric layers on opposing sidewalls of the plurality of first sacrificial layers;
replacing the plurality of first sacrificial layers with a plurality of sidewall protective layers; and
forming a plurality of control gates on sidewalls of the plurality of inter-gate dielectric layers.

13. The method as claimed in claim 12, wherein forming the plurality of floating gates and the plurality of inter-gate dielectric layers comprises:
forming a floating gate material layer on the opposing sidewalls of the plurality of first sacrificial layers and on the tunneling dielectric layer;
removing the floating gate material layer on top surfaces of the plurality of first sacrificial layers to form a plurality of floating gate layers;
forming an inter-gate dielectric material gate layer on the plurality of floating gate layers and on the plurality of first sacrificial layers; and
removing the inter-gate dielectric material gate layer and a portion of the floating gate layers on the top surfaces of the plurality of first sacrificial layers to form the plurality of inter-gate dielectric layers and the plurality of floating gates.

14. The method as claimed in claim 13, wherein forming the plurality of floating gate layers further comprises:
forming a second sacrificial layer on a sidewall of the floating gate material layer after forming the floating gate material layer,
wherein removing the floating gate material layer on top surfaces of the plurality of first sacrificial layers further comprises: removing the second sacrificial layer on the top surfaces of the plurality of first sacrificial layers.

15. The method as claimed in claim 14, wherein forming the plurality of inter-gate dielectric layers further comprises:
forming a third sacrificial layer on sidewalls of the plurality of floating gate layers and on a top surface of the floating gate layer;
removing the third sacrificial layer on the top surfaces of the plurality of first sacrificial layers, and the third sacrificial layer remains on the sidewall of the floating gate layer.

16. The method as claimed in claim 15, wherein forming the plurality of control gates comprises:
replacing the remaining third sacrificial layer with a control gate material layer.

17. The method as claimed in claim 15, wherein the second sacrificial layer and the first sacrificial layer comprise a same material.

18. The method as claimed in claim 15, wherein the second sacrificial layer and the first sacrificial layer comprise different materials.

19. The method as claimed in claim 12, wherein forming the plurality of floating gates further comprises:
forming a plurality of trenches along a second direction, wherein the second direction is different from the first direction, and the plurality of trenches penetrates the first sacrificial layer and the tunneling dielectric layer and contacts the substrate;
forming a plurality of isolation components in the plurality of trenches; and
replacing the first sacrificial layer between the plurality of isolation components with a plurality of sidewall protective layers.

20. The method as claimed in claim 12, further comprising:
forming a top protective layer on the control gate after forming the control gate.
